(19) United States
(12) Patent Application Publication
(10) Pub. No.: US 2010/0126578 A1
(43) Pub. Date: May 27, 2010

(54) WORKING ELECTRODE, DYE-SENSITIZED SOLAR CELL HAVING SAME AND METHOD FOR MAKING SAME

(75) Inventor: SHAO-KAI PEI, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/502,378

(22) Filed: Jul. 14, 2009

(30) Foreign Application Priority Data
Nov. 27, 2008 (CN) 200810305766.5

(51) Int. Cl. H01L 31/00; H01L 31/18

(52) U.S. Cl. 136/256; 438/57; 977/755; 438/478; 257/E21.09

(57) ABSTRACT

An exemplary working electrode includes a transparent conductive substrate, a nanorod layer formed on the transparent conductive substrate, and a porous semiconductor layer formed on the nanorod layer. The nanorod layer includes a plurality of nanorods. Each nanorod is comprised of a material selected from the group consisting of iridium-iridium oxide and ruthenium-ruthenium oxide. The porous semiconductor layer has a dye sensitizer adsorbed thereon.

### BACKGROUND

1. Technical Field

The present disclosure relates to a working electrode, a dye-sensitized solar cell having the working electrode and a method for making the working electrode.

2. Description of Related Art

A dye-sensitized solar cell is a relatively new class of low-cost solar cell, that belongs to the group of thin film solar cells. However, solar conversion efficiency of current dye-sensitized solar cell is not high enough.

Therefore, what is needed, is a new dye-sensitized solar cell, which can overcome the above-mentioned problem.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view of a dye-sensitized solar cell connected with an external circuit according to an exemplary embodiment.

FIG. 2-3 shows successive stages of forming a working electrode of the dye-sensitized solar cell of FIG. 1.

### DETAILED DESCRIPTION

Embodiments will now be described in detail below with reference to the drawings.

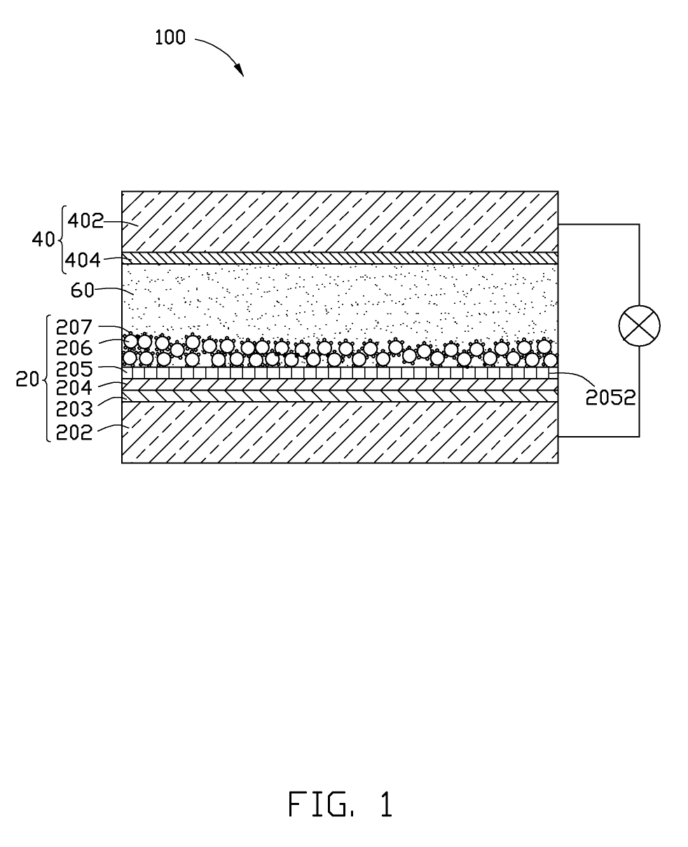

Referring to FIG. 1, a dye-sensitized solar cell 100 according to a present embodiment is shown. The dye-sensitized solar cell 100 includes a working electrode 20, a counter electrode 40, and a carrier transport layer 60.

The counter electrode 40 includes a transparent conductive substrate 402 and a metal layer 404 formed on the transparent conductive substrate 402. The transparent conductive substrate 402 can be a glass with a conductive oxide film formed on the glass. The metal layer 404 is formed on a surface of the counter electrode 40 facing the working electrode 20. The carrier transport layer 60 can be ion conductors such as a liquid electrolytic substance and an electrolytic polymer.

The working electrode 20 includes a transparent conductive substrate 202, a first metal layer 203 formed on the transparent conductive substrate 202, a metal oxide layer 204 formed on the first metal layer 203, an iridium-iridium oxide nanorod layer 205 formed on the metal oxide layer 204, and a porous semiconductor layer 206 formed on the iridium-iridium oxide nanorod layer 205. A dye sensitizer 207 is adsorbed in the porous semiconductor layer 206. The carrier transport layer 60 is arranged between the counter electrode 40 and the porous semiconductor layer 206. Alternatively, the iridium-iridium oxide nanorod layer 205 can be a ruthenium-ruthenium oxide nanorod layer 205.

The first metal layer 203 can be made of a material selected from the group consisting of nickel, palladium, and gold. The first metal layer 203 functions as a catalyst.

The metal oxide layer 204 can be made of a material selected from the group consisting of titanium oxide, copper oxide and aluminum oxide.

The iridium-iridium oxide nanorod layer 205 includes a plurality of iridium-iridium oxide nanorods 2052. Each iridium-iridium oxide nanorod 2052 is substantially parallel to each other and is substantially perpendicular to a surface of the metal oxide layer 204.

The porous semiconductor layer 206 can be made of a material selected from the group consisting of titanium oxide, zinc oxide. In the present embodiment, the porous semiconductor layer 206 is made from titanium oxide. The dye sensitizer 207 can be made of zinc phthalocyanine (ZnPc).

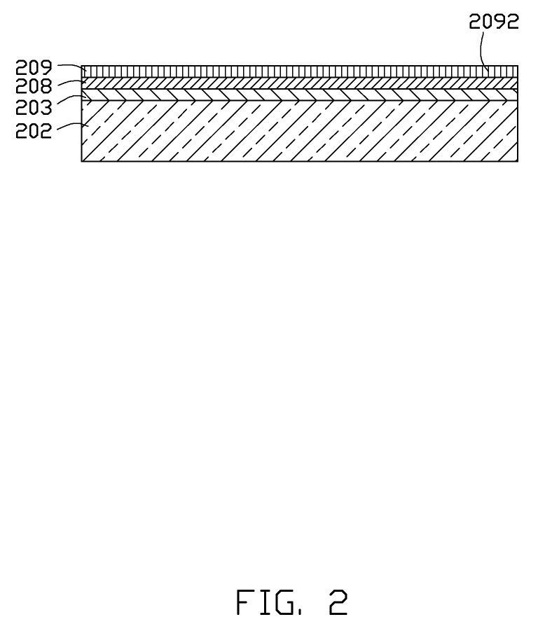

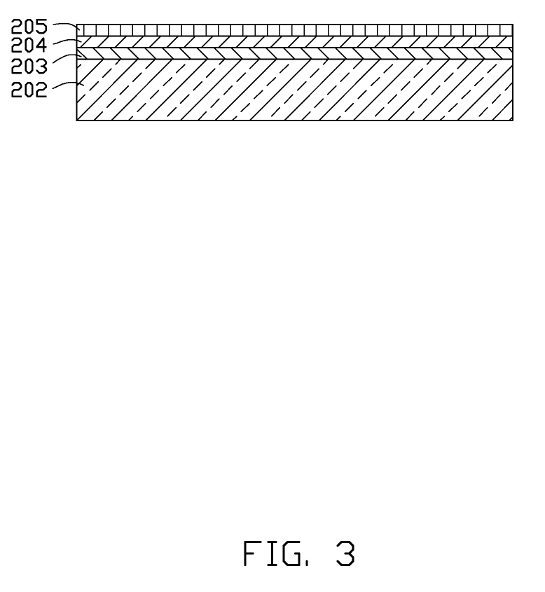

Referring to FIGS. 1-3, the working electrode 20 can be made using the following method:

In step 1, the first metal layer 203 is formed on the transparent conductive substrate 202 by magnetron sputtering.

In step 2, a second metal layer 208 is formed on the first metal layer 203 by magnetron sputtering.

In step 3, an iridium oxide nanorod layer 209 is formed on the second metal layer by chemical vapor deposition (CVD). The iridium oxide nanorod layer 209 includes a plurality of iridium oxide nanorods 2092.

In step 4, iridium oxide of the iridium oxide nanorod layer 209 is deoxidized with the first metal layer 203 as a catalyst in such a condition that a temperature is in a range from 500° C. to 600° C. and a vacuum degree is less than 6.67×10⁻³ Pa. Accordingly, the iridium-iridium oxide nanorod layer 205 is obtained, and, simultaneously, the second metal layer 208 is oxidized to form the metal oxide layer 204.

In step 5, a porous semiconductor layer 205 is formed on the iridium-iridium oxide nanorod layer 205 by spray pyrolysis.

In step 6, a zinc phthalocyanine solution is prepared, and the zinc phthalocyanine is adsorbed in the porous semiconductor layer 206, thus forming the porous semiconductor layer 206 with the dye sensitizer 207 adsorbed.

In use, when the dye-sensitized solar cell 100 is illuminated by the sun, photons striking the dye sensitizer 207 with enough energy to be absorbed will create an excited state of the dye sensitizer 207, from which an electron can be injected directly into a conduction band of the titanium oxide of the porous semiconductor layer 206. Then the electron is sequentially injected into the iridium-iridium oxide nanorod layer 205, the metal oxide layer 204, the first metal layer 203, and the transparent conductive substrate 202. The electron is then transmitted to the counter electrode 40 via an external circuit 80. The dye sensitizer 207 in oxidation state is deoxidized by the carrier transport layer 60, then the carrier transport layer 60 in the oxidation state receives the electron from the counter electrode 40 after flowing through the external circuit 80. In this way, a current is formed in the external circuit 80 and the transmission process of the electron is done.

In the present embodiment, the iridium-iridium oxide nanorod layer 205 includes a plurality of one-dimensional iridium-iridium oxide nanorods 2052. The electron can be injected into the transparent conductive substrate 402 via the iridium-iridium oxide nanorod layer 205 more quickly than ordinary films. Hence, the efficiency of electron transmission is enhanced. Accordingly, the solar conversion efficiency of the dye-sensitized solar cell is increased.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope of the appended claims.

What is claimed is:

1. A working electrode comprising:
a transparent conductive substrate;
a nanorod layer formed on the transparent conductive substrate, the nanorod layer comprising a plurality of nanorods, each nanorod being comprised of a material selected from the group consisting of iridium-iridium oxide and ruthenium-ruthenium oxide; and
a porous semiconductor layer with a dye sensitizer thereon, the porous semiconductor being formed on the nanorod layer.

2. The working electrode of claim 1, wherein each nanorod is substantially parallel to each other.

3. The working electrode of claim 1, wherein each nanorod is substantially perpendicular to a surface of the transparent conductive substrate.

4. The working electrode of claim 1, further comprising a metal layer sandwiched between the transparent substrate and the nanorod layer.

5. The working electrode of claim 1, further comprising a metal oxide layer sandwiched between the transparent substrate and the nanorod layer.

6. A dye-sensitized solar cell comprising:
a counter electrode;
a working electrode, the working electrode comprising:
a transparent conductive substrate;
a nanorod layer formed on the transparent conductive substrate, the nanorod layer comprising a plurality of nanorods, each nanorod being comprised of a material selected from the group consisting of iridium-iridium oxide and ruthenium-ruthenium oxide; and
a porous semiconductor layer with a dye sensitizer thereon, the porous semiconductor being formed on the nanorod layer, the porous semiconductor layer facing the counter electrode; and
a carrier transport layer sandwiched between the counter electrode and the working electrode.

7. The dye-sensitized solar cell of claim 6, wherein each nanorod is substantially parallel to each other.

8. The dye-sensitized solar cell of claim 6, wherein each nanorod is substantially perpendicular to a surface of the transparent conductive substrate.

9. The dye-sensitized solar cell of claim 6, further comprising a metal layer sandwiched between the transparent substrate and the nanorod layer.

10. The dye-sensitized solar cell of claim 6, further comprising a metal oxide layer sandwiched between the transparent substrate and the nanorod layer.

11. A method of making a working electrode, the method comprising:
forming a first nanorod layer on a transparent conductive substrate, the first nanorod layer comprising a plurality of first nanorods, each first nanorod being comprised of a material selected from the group consisting of iridium oxide and ruthenium oxide;
deoxidizing the first nanorod layer to form a second nanorod layer, the second nanorod layer comprising a plurality of second nanorods, each second nanorod being comprised of a material selected from the group consisting of iridium-iridium oxide and ruthenium-ruthenium oxide; and
forming a porous semiconductor layer with a dye sensitizer adsorbed thereon.

12. The method of claim 11, further comprising: forming a first metal layer on the transparent conductive substrate before forming the first nanorod layer, wherein the first metal layer functions as a catalyst during the step of deoxidizing.
